(19) United States
(12) Patent Application Publication
(10) Pub. No.: US 2007/0094579 A1
(43) Pub. Date: Apr. 26, 2007

(54) METHOD FOR HANDLING AUDIO PACKET LOSS IN A WINDOWS® MEDIA DECODER

(76) Inventor: Miguel Cerrato Sanchez, Mataro (ES)

Correspondence Address: ERICSSON INC., 6300 LEGACY DRIVE, M/S EVR 1-C-11, PLANO, TX, 75024, US

(21) Appl. No.: 11/422,808

(22) Filed: Jun. 7, 2006

Related U.S. Application Data
(60) Provisional application No. 60/724,859, filed on Oct. 7, 2005.

(51) Int. Cl. H03M 13/00

(52) U.S. Cl. 714/776

(57) ABSTRACT

A method for re-synchronizing audio data with video data in a Windows Media decoder when Advanced Systems Format (ASF) packets are lost, comprising calculating the number of frames that have been lost by generating an Estimated Presentation Time (EPT) for each data frame in the WMA packet and comparing it to a Requested Presentation Time (RPT) of the WMA packet.

### CROSS-REFERENCE TO RELATED APPLICATIONS

This application claims the benefit of U.S. Provisional Application No. 60/724,859, filed Oct. 7, 2005, the disclosure of which is incorporated herein by reference.

### STATEMENT REGARDING FEDERALLY SPONSORED RESEARCH OR DEVELOPMENT

NOT APPLICABLE

### REFERENCE TO SEQUENCE LISTING, A TABLE, OR A COMPUTER PROGRAM LISTING COMPACT DISC APPENDIX

NOT APPLICABLE

### BACKGROUND OF THE INVENTION

The present invention relates to a method for handling audio packet loss in a Windows® media decoder.

One of the applications offered by mobile platforms in mobile devices such as cellular telephones, smart-phones, personal digital assistants (PDAs) and computers is the playback of multimedia data comprised of audio data and video data. One file format used for this data has been developed by Microsoft® Corporation and is referred to as Advanced Systems Format (ASF). ASF is an extensible file format designed to store synchronized multimedia data. It supports data delivery over a wide variety of networks and protocols, and is also suitable for local playback. The ASF file container stores the following in one file: audio, multi-bit-rate video, metadata (such as the file's title and author), and index and script commands (such as Uniform Resource Locators (URLS) and closed captioning).

Because each ASF file can be comprised of one or more media streams the ASF file header specifies the properties of the entire file, along with stream-specific properties. Multimedia data, stored after the file header in an ASF file, references a particular media stream number to indicate its type and purpose. The delivery and presentation time of all media stream data is aligned to a common timeline.

ASF file format supports the transmission of live content over a network. For this, the file is transmitted over the air in ASF packets. ASF files are logically comprised of different parts containing multimedia data, i.e., packets of audio and video data, and other types of information as referenced above. While ASF files may be edited, ASF file format is specifically designed for streaming and/or local playback of multimedia content.

While playing back the multimedia data using a mobile platform in a mobile device, data consisting of audio data and video data must be synchronized. However, audio data and video data are processed in different ways and, as such, suffer different time delays. There exists a conventional method of handling these time delays, assuming no loss of frames, and resynchronizing the data.

However, a problem arises when streaming live content over the air and ASF packets are lost during transmission. An ASF packet in its turn contains several packets that can be of audio data or video and data. The conventional synchronization solutions are not well-suited to cope with these different packets and therefore audio data and video data can become un-synchronized, when for example playing back multimedia content.

An ASF packet usually corresponds to a known number of frames (minimum unit of audio to be played on the output of the decoder), so when an ASF packet is lost, it is known how many frames have been lost. Conventionally, in the case where video data is lost, the last frame that was displayed will be displayed again for every frame that has been lost. For the audio data, instead of reproducing the last frame that was played, silence is played back for every lost audio frame.

ASF packets can contain several Windows Media Video (WMV) and/or Windows Media Audio (WMA) packets, and these can contain one or more, or even parts of frames. With respect to the audio portion, an ASF packet contains an integer number of WMA packets and a WMA packet in its turn can contain encoded data for a number of WMA output frames and the encoded data for a frame can cross WMA packet boundaries.

WMA differs with other audio standards in the fact that the minimum unit of data fed into the decoder is a WMA packet and not a frame, although a frame remains the minimum unit of data on the output. The fact that a packet does not always have the same number of frames and that it does not always have an integer number of frames, means that it is impossible to know how many frames have been lost when an ASF packet is lost. Therefore, since it is not known how much data is lost, it conventionally cannot be determined for how long silence must be played back in order to keep the audio data synchronized with the video data.

Therefore, what is desired is a method which is able to resynchronize audio data with video data in the event of ASF packets comprising Windows Media Audio (WMA) frames are lost during streaming and/or local playback of multimedia content.

### BRIEF SUMMARY OF THE INVENTION

The present invention comprises a method for re-synchronizing audio data with video data in a Windows Media decoder when Advanced Systems Format (ASF) packets are lost, comprising calculating the number of frames that have been lost by generating an Estimated Presentation Time (EPT) for each data frame in the WMA packet and comparing it to a Requested Presentation Time (RPT) of the WMA packet.

The present invention uses a Requested Presentation Time (RPT) field of the ASF packet to synchronize audio data with video data using the RPT to calculate the amount of frames that have been lost during streaming and/or local playback of the multimedia content.

### BRIEF DESCRIPTION OF THE SEVERAL VIEWS OF THE DRAWING

FIG. 1 illustrates the logical structure of an ASF packet;

FIG. 2 illustrates the logical structure of a WMA packet;

FIG. 3 illustrates the process of decoding the audio data and calculating EPTs; and

FIG. 4 is a flow chart of the steps of a method for synchronizing audio data and video data.

### DETAILED DESCRIPTION OF THE INVENTION

The present invention is a method that resynchronizes Windows Media Audio and Video without involving a reference clock, by calculating how much silence has to be played back i.e., the number of frames when ASF packets are lost from the audio data stream of a Window Media Audio (WMA) data file.

The present invention uses the Requested Presentation Time (RPT) field of the WMA packet to synchronize video data and audio data, without using a reference clock, by using the RPT to calculate the amount of frames that have been lost.

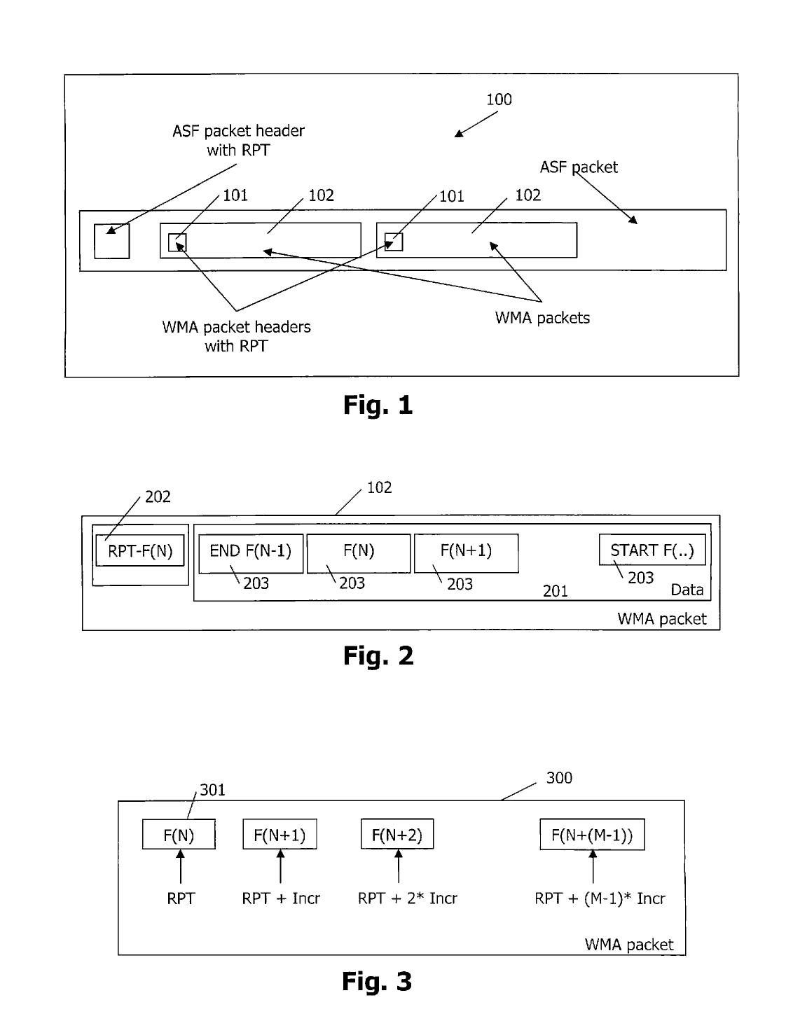

FIG. 1 illustrates the logical structure of an ASF packet 100. An embodiment of the present invention is a method to maintain synchronization between audio data and video data by means of RPT stamps 101 that are supplied with each WMA packet 102.

FIG. 2 shows a logical structure of a WMA packet 102. The WMA packet 102 comprises data 201 to be decoded and information associated to it, such as the RPT 202. The data is divided into frames 203, and in a general situation there can be data left from a frame that started at a previous packet (e.g., Frame (N−1), a number of full frames (Frame (N), Frame (N+1). . . ) and data correspondent to a frame that does not fit into the previous packet and will end in the next packet (Frame ( . . . )). Further, the RPTs corresponds to the requested presentation time for the start of the first complete decoded frame contained within the WMA packet, Frame (N). Notably, data cannot be split into frames for WMA decoders before decoding like for other audio decoders.

As seen in FIG. 3, the process of decoding the audio data and calculating EPTs occurs as follows: the WMA decoder reads the data stream from a WMA packet 300 and delivers frames. Frame (N) 301 will be presented at a presentation time marked by the RPT and subsequent EPTs are calculated for the other frames, if any, in the packet. The EPTs for each output frame are calculated from the previous one by adding an increment as follows:
EPT(N+1)=RPT(N)+PT_Increment
EPT(N+2)=EPT(N+1)+PT_Increment

This is done until a new WMA packet and a new RPT are received. The Presentation Time (PT) increment is calculated with the number of samples for a frame (OutFrameSamples) and the number of samples per second (nSamplesPerSec) as follows:
PR Increment=1000000*OutFrameSamples/nSamplesPerSec

The number of samples per frame is determined by the audio sample rate and the number of samples per second is information available in the ASF file.

The process for calculating lost frames is as follows: when receiving a new WMA packet with a new RPT, there will be two presentation times available, the calculated one (referred to as EPT) and the actual one delivered by the WMA packet information (referred to as RPT). Any redundant information permits an estimate of whether there has been a loss of data or not, and if so how many frames have been lost. Theoretically the amount of lost frames can be calculated as:
LostFrames=(RPT−EPT)/PT_Increment

However, hardware limitations make this calculation much more complex, as variables have a limited scope and will wrap around and, further, the calculations are not exact.

The process of synchronizing audio occurs as follows: If the estimated value of the number of frames that have been lost is zero (0), the decoding continues. But if the estimated value of lost frames is not zero, a certain number of frames (silence) are delivered for playback and EPTs calculated, until the estimated time stamps gets close to the last time stamp that was received. Note that this can be done without involving a reference clock.

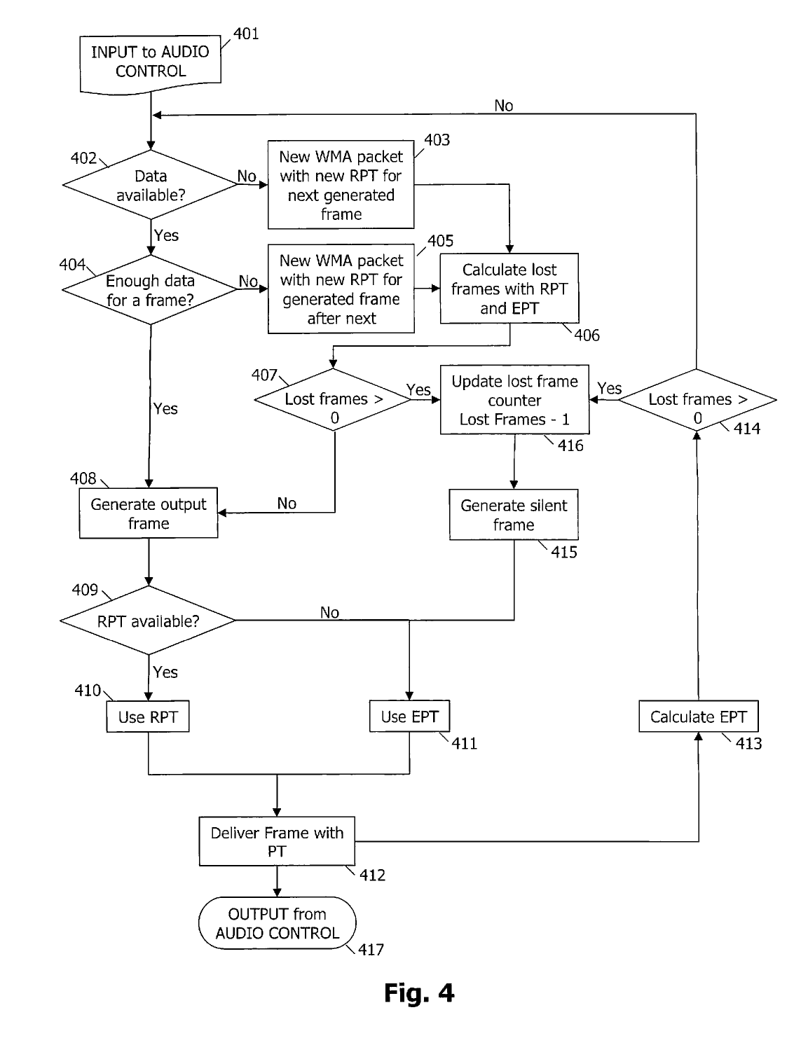

The flow chart of FIG. 4 describes the steps of the present invention. The process commences when a new WMA packet is received. Each packet has one or more frames and/or can be part of a frame. As seen therein, in step 401, the WMA packet is accepted as an input to audio control.

At step 402, a determination is made as to whether audio data is available. In step 403, if no audio data is available, the packet is accepted and the RPT, will be used for the first frame. In step 404, if there is data available, a determination is made of whether there is enough data for a frame. In step 405, if there is not enough data for a frame, the packet is accepted and the RPT is for the second frame (frame after next). Note that in steps 403 and 404-405, because a new packet was obtained with a new RPT, there is a calculation, in step 406, of whether there were lost frames. In step 407, since there was enough data available to decode a full frame, a packet is not taken, and such action is put on hold.

A determination is made at step 407 as to whether there were any lost frames. If not, in step 408, a new output (audio) frame is generated (decoded). If, in step 409, it is determined that there is an available RPT, it is used in step 410 and the frame is delivered at step 412, resulting in an output from audio control at step 417. As described below, if there is not an available RPT, then an estimated presentation time (EPT) is used at step 411, and the frame is delivered at step 412, resulting in an output from audio control at step 417. The RPTs or EPTs are fed back for the calculation of EPTs at step 413. Referring back to step 407, if there were lost frames, instead of decoding a frame, an empty frame is delivered at step 415 and the lost frames counter is decremented by one (lost frames=lost frames−1) at step 416. At step 411, an EPT is delivered with a silent (empty) frame.

After delivering an empty frame at step 411, a calculation of a new EPT is performed and if lost frames are >0 which occurs if not all the frames calculated as having been lost were delivered, then the counter is updated again and another empty frame is delivered.

As will be recognized by those skilled in the art, the innovative concepts described in the present application can be modified and varied over a wide range of applications. Accordingly, the scope of patented subject matter should not be limited to any of the specific exemplary teachings discussed above, but is instead defined by the following claims.

What is claimed:

1. A method for re-synchronizing audio with video in a Windows Media decoder when Advanced Systems Format (ASF) packets are lost, comprising calculating the number of frames that have been lost by generating an Estimated Presentation Time (EPT) for each data frame in the WMA packet and comparing it to a Requested Presentation Time (RPT) of the WMA packet.

2. The method of claim 1, further comprising stopping, by a decoder, the decoding of frames until the EPT is substantially equal to the RPT of the WMA packet received by the decoder.

3. The method of claim 2, wherein the re-synchronization of video data and audio data is accomplished without a reference clock.

4. The method of claim 3, as implemented in a mobile platform in a mobile device.

5. The method of claim 4, as implemented in a mobile platform in a mobile device selected from the group consisting of a cellular telephone, smart-phone, personal digital assistant (PDA) and computer.

6. A method of handling audio packet loss in a Windows® media decoder comprising:
providing a packet input to an audio control;
determining whether data is available in the audio control (or decoder) at the input;
if no data is available, accepting the packet and using a requested presentation time (RPT), for the first frame;
if data is available, determining whether there is enough data for a frame;
if there is not enough data for a frame, accepting the packet and setting the RPT at the second frame (frame after next);
calculating lost frames when a new packet is obtained with a new RPT;
holding further action if there is enough data available to decode a full frame, and a packet is not taken;
determining whether there are any lost frames;
if there are no lost frames, generating a new output (audio) frame;
if it is determined that there is an available RPT, using it and delivering a frame, resulting in an output from audio control;
if there is not an available RPT, then using an estimated presentation time (EPT), and delivering the frame, resulting in an output from the audio control;
feeding back the RPT or EPT for calculation of the next EPT;
if there are lost frames, instead of decoding a frame, delivering an empty frame and updating the lost frames counter by advancing by the amount: lost frames−1;
delivering an EPT with an empty frame;
after delivering an empty frame, calculating a new EPT if lost frames are greater than zero; and updating the counter and delivering the empty frame.

7. The method of claim 6, wherein the re-synchronization of video data and audio data is accomplished without a reference clock.

8. The method of claim 6, as implemented in a mobile platform in a mobile device.

9. The method of claim 6, as implemented in a mobile platform in a mobile device selected from the group consisting of a cellular telephone, smart-phone, personal digital assistant (PDA) and computer.

10. A method of handling audio packet loss in a Windows® Media decoder without a reference clock, comprising:
dividing data in a Windows Media Audio (WMA) packet (contained in Advanced Systems Format (ASF) packet) into at least one frame;
using, by an audio control, a requested presentation time (RPT) corresponding to the start of the first complete decoded WMA frame contained within the WMA packet;
comparing the RPTs to estimated presentation times (EPTs);
based on the comparison, determining the lost WMA frames in at least one ASF packet;
reading, by a WMA decoder, the data stream from the ASF packet;
presenting each of the plurality of WMA frames at a presentation time marked by the respective PT (RPTs and EPTs); and
playing back silence for each of the lost WMA frames.

11. The method of claim 10, further comprising generating, by audio control, each EPT by adding an increment to the prior presentation time (RPT or EPT).

12. The method of claim 10, wherein the presentation time generating step is done until a new WMA packet and a new RPT are received by the audio control.

13. The method of claim 12, wherein each presentation time increment is calculated based on the number of samples for a frame and the number of samples per second.

14. The method of claim 13, wherein the number of samples per frame is determined by the audio sample rate.

15. The method of claim 13, wherein the number of samples per second is information available in the ASF file.

16. The method of claim 10, as implemented in a mobile platform of a mobile device.

17. The method of claim 10, as implemented in a mobile device selected from the group consisting of a cellular telephone, smart-phone, personal digital assistant (PDA) and computer.

18. A method for re-synchronizing audio with video in a Windows® Media decoder, comprising:
correlating presentation time (PT) increments of a requested presentation time (RTP) field with audio frames of a Windows Media Audio (WMA) packet;
comparing the correlated PT increments to an RPT value provided by the WMA packet; and
based on the comparison, estimating whether there has been a loss of audio frames.

19. The method of claim 18, wherein the number of lost frames is calculated as follows:
Lost Frames=(RPT−estimated presentation time)/PT Increment.

20. The method of claim 18, as implemented in a mobile platform of a mobile device.

21. The method of claim 20, as implemented in a mobile device selected from the group consisting of a cellular telephone, smart-phone, personal digital assistant (PDA) and computer.

22. An apparatus adapted to handle audio packet loss in a Windows® Media decoder without a reference clock, comprising:
a means for dividing data in a Windows Media Audio packet (contained in an Advanced Systems Format (ASF) packet) into at least one Windows Media Audio (WMA) frame;
a decoder adapted to use a requested presentation time (RPT) to correspond to the start of the first complete decoded WMA frame contained within the WMA packet;
a means adapted to correlate a separate RPT to each at least one ASF packet after the complete decoded WMA frame;
a means adapted to compare the EPTs to a RPT set forth in an WMA packet and determine the lost WMA frames; and
a decoder adapted to read the data stream from the WMA packet, present each of the plurality of WMA frames at a presentation time (PT) marked by the PT (RPT if available, otherwise EPT), and play back silence for each of the lost WMA frames of a lost ASF packet.

23. The apparatus of claim 22, further comprising the decoder being adapted to generate new PT (EPTS) by adding an increment to the prior RPT or EPT.

24. The apparatus of claim 23, wherein the decoder is adapted to generate each generated EPT by adding an increment to the prior RPT or EPT until a new WMA packet and a new RPT are received by the decoder.

25. The apparatus of claim 24, wherein each PT increment generated by the decoder is calculated based on the number of samples for a frame and the number of samples per second.

26. The apparatus of claim 24, wherein the number of samples per frame is determined by the audio sample rate.

27. The apparatus of claim 26, wherein the number of samples per second is information available in an ASF file.

28. The apparatus of claim 22, as implemented in a mobile platform in a mobile device.

29. The apparatus of claim 28, as implemented by a mobile device selected from the group consisting of a cellular telephone smart-phone, personal digital assistant (PDA) and computer.
